(19) United States
(12) Patent Application Publication
(10) Pub. No.: US 2009/0134527 A1
(43) Pub. Date: May 28, 2009

(54) STRUCTURE OF THREE-DIMENSIONAL STACKED DICE WITH VERTICAL ELECTRICAL SELF-INTERCONNECTIONS AND METHOD FOR MANUFACTURING THE SAME

(76) Inventor: Shu-Ming CHANG, Hsinchu (TW)

Correspondence Address: BIRCH STEWART KOLASCH & BIRCH, PO BOX 747, FALLS CHURCH, VA, 22040-0747, US

(21) Appl. No.: 12/201,803

(22) Filed: Aug. 29, 2008

(30) Foreign Application Priority Data
Nov. 26, 2007 (TW) 96144723

(51) Int. Cl. H01L 23/538; H01L 21/58

(52) U.S. Cl. 257/777; 438/109; 257/E21.505; 257/E23.169

(57) ABSTRACT

This invention provides a structure of three-dimensional stacked dice with vertical electrical self-interconnections and a method for manufacturing the same. A respective electrical conductive layer is formed in a buried layer of each of the stacked dice, and being extended and exposed to a sidewall of the respective die. An electroless plating process is performed to deposit metal on exposed portions of the respective electrical conductive layers. The metal isotropically grows along the sidewalls of the stacked dice to form a vertical electrical conductive wire connecting the respective conductive layers. The vertical electrical self-interconnections of the three dimensional stacked dice are established.

### BACKGROUND OF THE INVENTION

1. Field of the Invention

The present invention relates to a structure of three-dimensional stacked dice and a method for manufacturing the same. More particularly, the present invention relates to a structure of three-dimensional stacked dice with vertical electrical self-interconnections and a method for manufacturing the same.

2. Description of the Related Art

In order to meet the demands for electronic devices of compactness, power-saving capability and increased efficiency, the existing package and wiring techniques relating to the conventional two-dimensional (2D) semiconductor dice are not sufficient enough and need to be further improved. In this case, it is possible to efficiently solve the technical issues caused by the techniques relating to the conventional two-dimensional dice by changing the two-dimensional stacking scheme into a three-dimensional (3D) manner. By applying the three-dimensional stacking schemes, the device density per area is increased while the dimension of dice and the energy consumption can be reduced.

U.S. Pat. No. 5,279,991 discloses a method for manufacturing a structure of three-dimensional stacked dice involving the steps of sawing the wafer to singulate each die therefrom, and then stacking the dice and forming a lateral connection of the stacked dice by means of metal sputtering and photolithography process. The method for manufacturing a structure of three-dimensional stacked dice as disclosed in respective U.S. Pat. Nos. 5,517,057, 5,502,667, 5,561,622, 5,563,086, 5,614,277, 5,648,684, 5,763,943, 5,907,178 and 5,930,098 involves the steps of sawing the wafer for singulating the individual dice therefrom, stacking the dice to be stacked, and then forming the lateral connection of the dice by means of metal sputtering and photolithography process. All of the mentioned methods are applicable for stacking the dice having the same size, while the dice having different sizes are placed on the top of the stacked dice and the connection thereof needs to be achieved by means of wire bonding. In U.S. Pat. No. 6,177,296, a method for manufacturing a structure of three-dimensional stacked dice is disclosed, in which the individual dice are singulated from the wafer by sawing and then stacked, and the lateral connection of the stacked dice is formed by the application of conductive adhesive. As to the method for manufacturing a structure of three-dimensional stacked dice as disclosed in U.S. Pat. No. 6,188,129, it involves a further step of directly forming solder bumps on the sidewall of the stacked dice in addition to the steps of sawing the wafer for singulating the individual dice therefrom, stacking the dice to be stacked, and forming the lateral connection of the dice by means of metal sputtering and photolithography process. In the method for manufacturing a structure of three-dimensional stacked dice as disclosed in U.S. Pat. No. 7,102,238, the metallic connection is formed on the respective front side and back side of the wafer and the sidewall of the die periphery in wafer-level, while the electrical connection between the stacked dice is achieved by solder bumps positioned therebetween. As to U.S. Pat. No. 7,208,343, the disclosed method for manufacturing a structure of three-dimensional stacked dice involves the steps of singulating the individual dice from the wafer by sawing, stacking the dice to be stacked, and then forming the lateral connection of the stacked dice by using the conductive adhesive.

The above-mentioned methods for manufacturing the structure of three-dimensional stacked dice are all disadvantageous in the use of extremely expensive equipments as well as the complicated and time-consuming processes, so that the product cost for those structures is extremely high. Accordingly, it is desired to provide a structure of three-dimensional stacked dice and a method for manufacturing the same with relatively lower fabrication costs.

### SUMMARY OF THE INVENTION

The present invention provides a structure of three-dimensional stacked dice with self-interconnections and a method for manufacturing the same, in which a low-cost electroless plating technique different from the conventional photolithography process is adopted for establishing vertical electrical self-interconnections of the three-dimensional stacked dice.

The structure of three-dimensional stacked dice provided according to the present invention includes: a plurality of dice stacked from bottom to top, at least two of which having a plurality of metal pads corresponding to at least a sidewall of die; a plurality of first insulating layers respectively formed on a first surface of each of the dice to expose the metal pads, and on each of the metal pads an electrical contact passing through the first insulating layer is formed; a plurality of electrical conductive layers respectively formed on the first insulating layer of each of the dice and including a plurality of electrical conductive wires extending to the sidewall of die corresponding to the metal pads, wherein each of the metal pads is electrically connected to a corresponding one of the electrical conductive wires via the electrical contact; a plurality of second insulating layer formed on the first insulating layer of each of the dice cover the die and expose the electrical conductive wires corresponding to the sidewall of die; and a plurality of vertical electrical conductive wires formed on the sidewall of die and electrically connected to the electrical conductive wires exposed to the sidewall of die, so as to establish the vertical electrical self-connections of the three-dimensional stacked dice.

In a further aspect, the method for manufacturing the structure of three-dimensional stacked dice with vertical electrical self-interconnections as provided according to the present invention includes the steps of: providing a wafer having a plurality of dice formed thereon, wherein between adjacent two of the dice a scribe line is formed and each of the dice has a plurality of metal pads; forming a recess on each of the scribe lines on the wafer; forming a first insulating layer on the wafer and forming a plurality of openings therein so as to expose the metal pads; forming an electrical conductive layer on the first insulating layer, wherein the electrical conductive layer includes a plurality of electrical conductive wires extending across the recesses, resulting in the metal pads respectively electrically connected to one of the electrical conductive wires corresponding thereto; forming a second insulating layer on the electrical conductive layer; attaching a handling substrate to the second insulating layer; thinning the wafer at a bottom side thereof to a level corresponding to a position of the recess; removing the handling substrate whereby a wafer having the electrical conductive layer is obtained; stacking and aligned-bonding a plurality of wafers having the electrical conductive layer with each other; forming a groove in each of the scribe lines of the wafers that are aligned and bonded to each other, so as to laterally expose a portion of each of the electrical conductive wires; performing an electroless plating process so as to form a plurality of vertical electrical conductive wires at a sidewall of each of the grooves to electrically connect the electrical conductive wires that are laterally exposed; and sawing the wafers to form a plurality of three-dimensional stacked dice.

Moreover, the present invention also provides a further structure of three-dimensional stacked dice with vertical electrical self-interconnections, which includes at least two dice stacked with each other, each of which having a plurality of metal pads corresponding to at least a sidewall of die; an electrical conductive layer formed on a top surface of each of the dice and having a plurality of electrical conductive wires, wherein each of the metal pads is electrically connected to one of the electrical conductive wires corresponding thereto; a first insulating layer formed on a top surface of a lower die of the at least two dice to expose a portion of each of the electrical conductive wires; a second insulating layer formed on a top surface of an upper die of the at least two dice to cover the upper die and to laterally expose a portion of each of the electrical conductive wires; and a plurality of vertical electrical conductive wires formed on the sidewall of die of the upper die and respectively connecting the laterally exposed one of the electrical conductive wires with one of the electrical conductive wires corresponding to the lower die.

The present invention further provides a method for manufacturing three-dimensional stacked dice with vertical electrical self-interconnections, which includes the steps of: providing a die having a plurality of metal pads formed on a surface thereof; and performing an electroless plating process to form a metal layer on an outer surface of each of the metal pads, wherein the metal layers of adjacent two metal pads are electrically contact with each other.

Also, the present invention provides a further method for manufacturing three-dimensional stacked dice with vertical electrical self-interconnections, which includes steps of: providing a first die having a plurality of metal pads below a surface thereof; forming a first insulating layer on the surface of the first die to expose the metal pads thereof; providing a second die having a plurality of metal pads below a surface thereof; forming a second insulating layer on the surface of the second die to expose the metal pads thereof; forming a spacer layer on the first insulating layer of the first die; stacking the second die on the first die in a metal pad-to-metal pad manner; and performing an electroless plating process to form a metal contact between each pair of the metal pads corresponding thereto.

In the present invention, a simple electroless plating process, rather than the expensive technique relating to the formation of through silicon via (TSV), is adopted for establishing the vertical electrical self-interconnections of the three-dimensional stacked dice. The present invention provides a structure of three-dimensional stacked dice and a method for manufacturing the same in a cost-effective manner.

### BRIEF DESCRIPTION OF THE DRAWINGS

FIGS. 1A to 1B are schematic views showing the formation of electrical self-interconnections between the metal pads of a die;

FIGS. 2A to 2J are schematic cross-sectional views corresponding to various stages of a method for forming a structure of three-dimensional stacked dice with vertical electrical self-interconnections according to one embodiment of the present invention;

FIG. 3A shows a schematic top view of the structure of three-dimensional stacked dice of FIG. 2J;

FIG. 3B shows a schematic side view taken along line A-A′ of FIG. 3A;

FIG. 3C shows a schematic cross-sectional view taken along line B-B′ of FIG. 3A;

FIGS. 4A to 4D are schematic cross-sectional views showing various electrical connections of the structure of three-dimensional stacked dice of the present invention;

FIGS. 5A to 5C are schematic cross-sectional views corresponding to various stages of the method for forming a structure of three-dimensional stacked dice with vertical electrical self-interconnections according to a variance of the method corresponding to FIGS. 2A to 2J;

FIG. 6 shows a schematic cross-sectional view of the structure of three-dimensional stacked dice according to another embodiment of the present invention; and

FIG. 7 shows a schematic cross-sectional view of a structure of three-dimensional stacked dice with electrical self-interconnection between metal pads according to a still another embodiment of the present invention.

### DETAILED DESCRIPTION OF THE PREFERRED EMBODIMENTS

With reference to the following disclosures combined with accompanying drawings, the three-dimensional stacked dice with vertical electrical self-interconnections and the method for manufacturing the same according to the present invention are illustrated and understood.

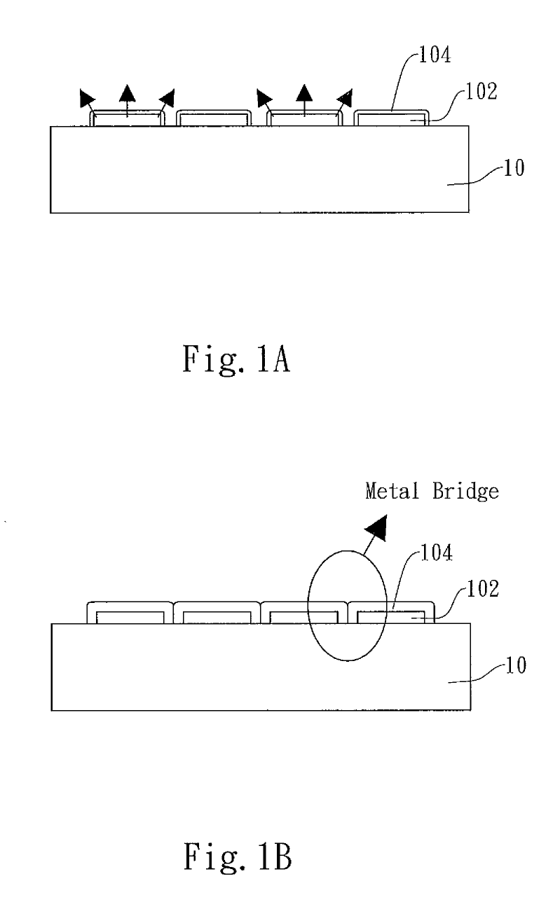

Please refer to FIGS. 1A and 1B schematically showing the formation of electrical self-interconnections between the metal pads 102 of the die 10, in which the electroless plating process is performed to deposit metal 104 onto each of the metal pads 102. The deposited metal 104 grows isotropically so that the electrical self-interconnection between the metal pads 102 is established. In the present invention, such concept is further adopted in the structure of three-dimensional stacked dice in which the vertical electrical connection between the three-dimensional stacked dice is established by the simple electroless plating process.

The structure of three-dimensional stacked dice with vertical electrical self-interconnections and the method for manufacturing the same according to the present invention are illustrated with reference to the following embodiments in combination with the accompanying drawings.

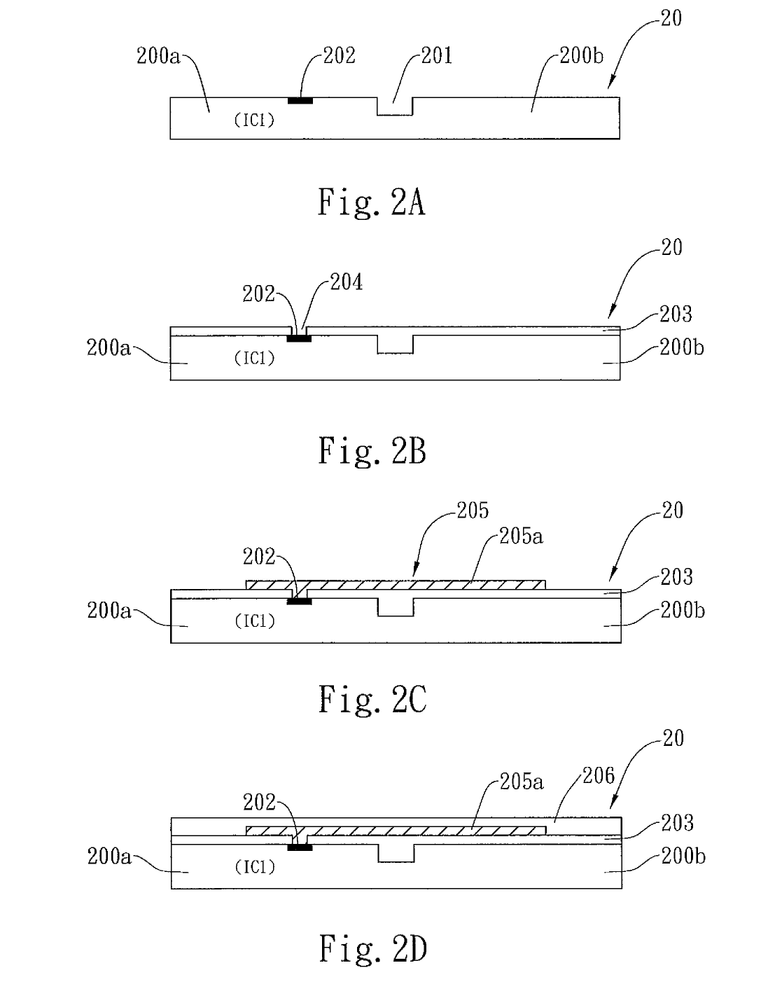

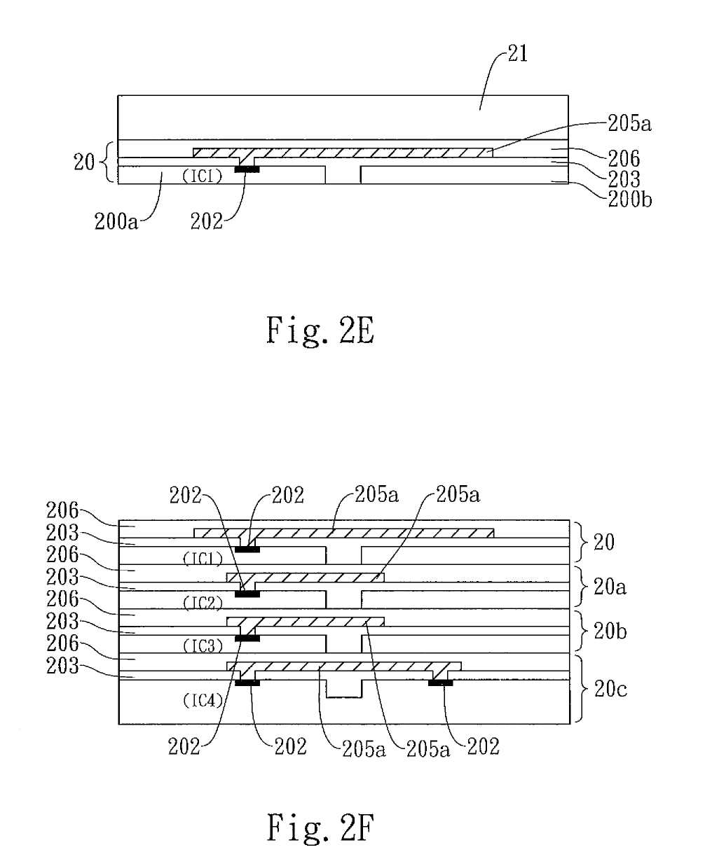

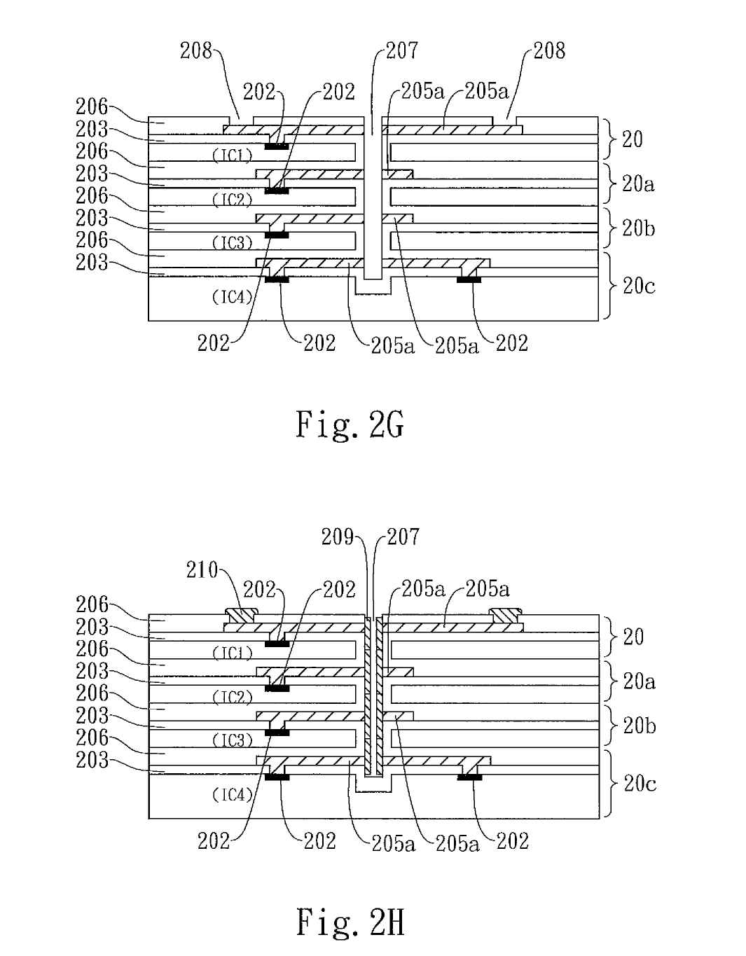

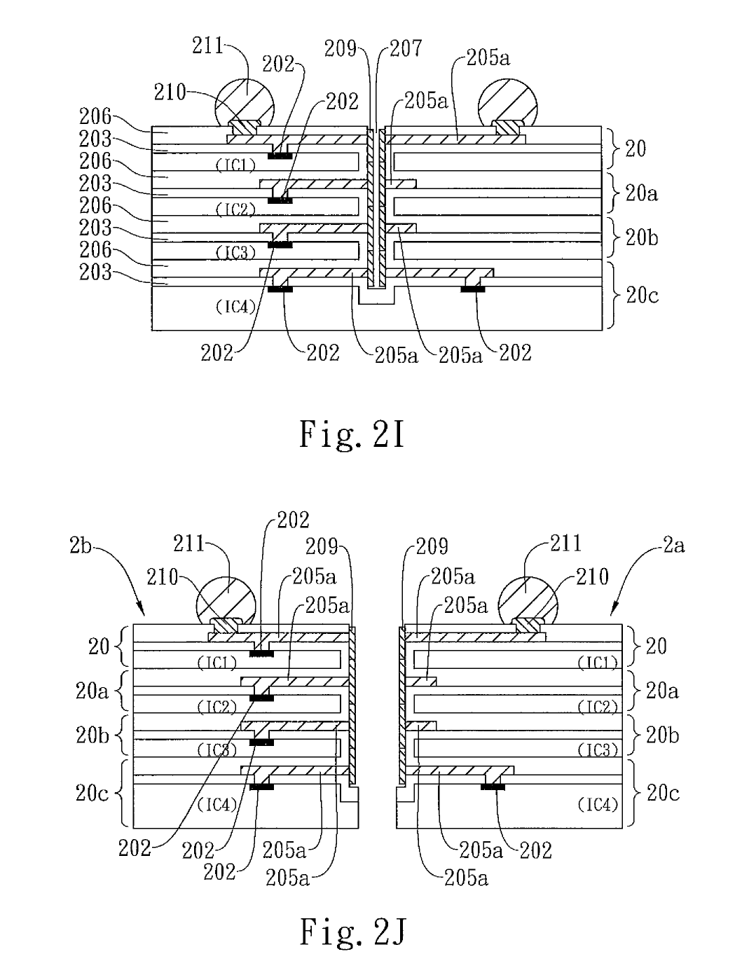

FIGS. 2A to 2J are schematic cross-sectional views corresponding to various stages of the method for forming a structure of three-dimensional stacked dice with vertical electrical self-interconnections according to one embodiment of the present invention. Referring to FIG. 2A, a wafer 20, such as a silicon wafer, is provided and thereon a plurality of dice 200a and 200b are formed. Between the adjacent dice 200a and 200b, a scribe line (not shown) is formed, and each of the dice 200a and/or 200b is provided with a plurality of metal pads 202, e.g. the aluminum pads. Referring to FIG. 2B, the recess 201 corresponding to each scribe line is formed by means of sawing, laser or etching, and then a first insulating layer 203 is provided on the wafer 20 and filling into the recess 201. Afterward, plural openings 204 are formed in the first insulating layer 203 so as to expose the metal pads 202. As shown in FIG. 2C, an electrical conductive layer 205 is formed on the first insulating layer 203. The electrical conductive layer 205 includes a plurality of electrical conductive wires that are respectively extended across the recesses 201, and the respective metal pads 202 are electrically connected to one of the electrical conductive wires 205a corresponding thereto. The electrical conductive layer 205 can be a metal layer of aluminum or copper, and can include a metal attachment layer of titanium (Ti), titanium tungsten (TiW) or chromium (Cr). Subsequently, a second insulating layer 206 is formed on the electrical conductive layer 205, as shown in FIG. 2D, where the second insulating layer 206 can be an insulating layer having the function of die-adhering. Referring to FIG. 2E, a handling substrate 21 is temporarily attached to the second insulating layer 206, and the wafer 20 is thinned at the back side thereof, i.e. the side opposing to that on which the handling substrate 21 is attached, to a level corresponding to the position of recess 201. Preferably, the thinned wafer according to the present invention has a thickness of less than 20 μm. Afterward, the handling substrate 21 is removed from the wafer 20, and a thinned wafer having the electrical conductive layer 205 is thus fabricated. Referring to FIG. 2F, the above-mentioned steps are repeated so that a number of thinned wafers 20a and 20b having the respective electrical conductive layer 205 are fabricated. These thinned wafers 20a and 20b having the respective electrical conductive layer 205 are bonding with the mentioned wafer 20 as well as a un-thinned wafer 20c having the electrical conductive layer 205, wherein the second insulating layer 206 can function as a die-adhering layer, or a further adhesive layer (not shown) is applied between neighboring wafers, for bonding the wafers with each other. As shown in FIG. 2G, in each scribe line of the bonded wafers 20, 20a, 20b and 20c, a groove 207 is formed so as to laterally expose a portion of each electrical conductive wire 205a. In this stage, plural openings 208 are also formed in the second insulating layer 206 of the top wafer 20 so as to expose a portion of surface of the electrical conductive layer 205a. Referring to FIG. 2H, the electroless plating process is performed to deposit a metal layer onto the laterally exposed portions of the electrical conductive wires 205a. Then the metal layer isotropically grows so that the adjacent metal layers can contact with each other, and a vertical electrical conductive wire 209 connecting the electrical conductive wires 205a corresponding thereto is thus established. Moreover, a plurality of metal contacts 210 is provided to cover the exposed portions of the second insulating layer 206 of the top wafer 20, with which one of the metal pads 202 corresponding thereto is electrically contact. By means of the above-mentioned electroless plating process, plural vertical electrical conductive wires 209 as mentioned on the sidewalls of each of the grooves 207 of the respective stacked wafers 20, 20a, 20b and 20c are formed. The vertical electrical conductive wires 209 and the metal contacts 210 can include copper, nickel, tin, gold or a combination thereof. Next, conductive bumps 211, such as solder bumps, are formed on the metal contacts 210 of the top wafer 20 so as to provide an electrical conductive path to external, as shown in FIG. 2I. Referring to FIG. 2J, the structures of three-dimensional stacked dice with vertical electrical self-interconnections 2a and 2b are fabricated after the stacked wafers are sawed.

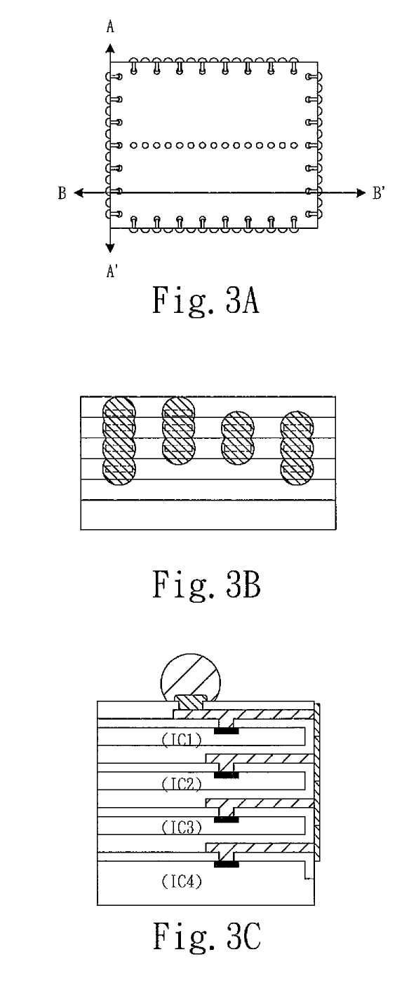

FIG. 3A shows a schematic top view of the structure of three-dimensional stacked dice with vertical electrical self-interconnections 2a or 2b of FIG. 2J, FIG. 3B shows a schematic side view taken along line A-A′ of FIG. 3A, and FIG. 3C shows a schematic cross-sectional view taken along line B-B′ of FIG. 3A, wherein the structure as shown in FIG. 3C is corresponding to the structure of three-dimensional stacked dice 2b of FIG. 2J, and the reference numerals thereof are omitted for simplicity.

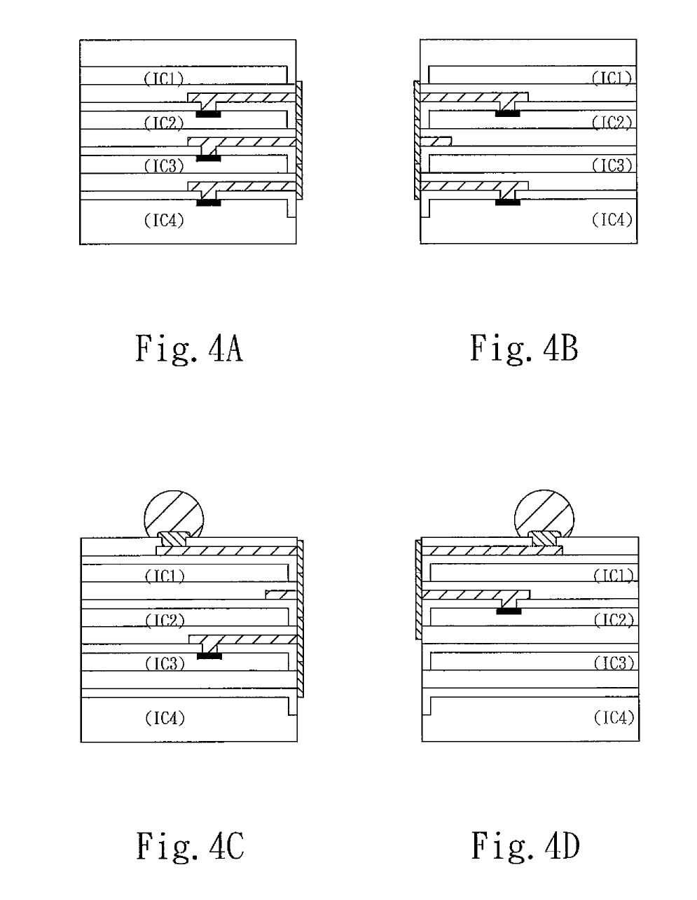

The structure of three-dimensional dice with vertical electrical self-interconnections formed by the method according to present invention can has different types of vertical electrical connections, as shown in FIGS. 4A to 4D, respectively. With reference to FIG. 4A, the vertical electrical connection is established from the second die, through the third die, to the fourth die (IC2-IC3-IC4), whereas the vertical electrical connection as shown in FIG. 4B is established between the second die and the fourth die (IC2-IC4). Referring to FIG. 4C, it shows that the electrical connection is established from the third die (IC3) to the external, while FIG. 4D shows the electrical connection is established from the second die (IC2) to the external. Moreover, if the lowest die is to be electrically connected to the external, the dice located in other layers can be designed as having an electrical conductive layer not connected to the aluminum pads thereof formed across the adjacent scribe lines.

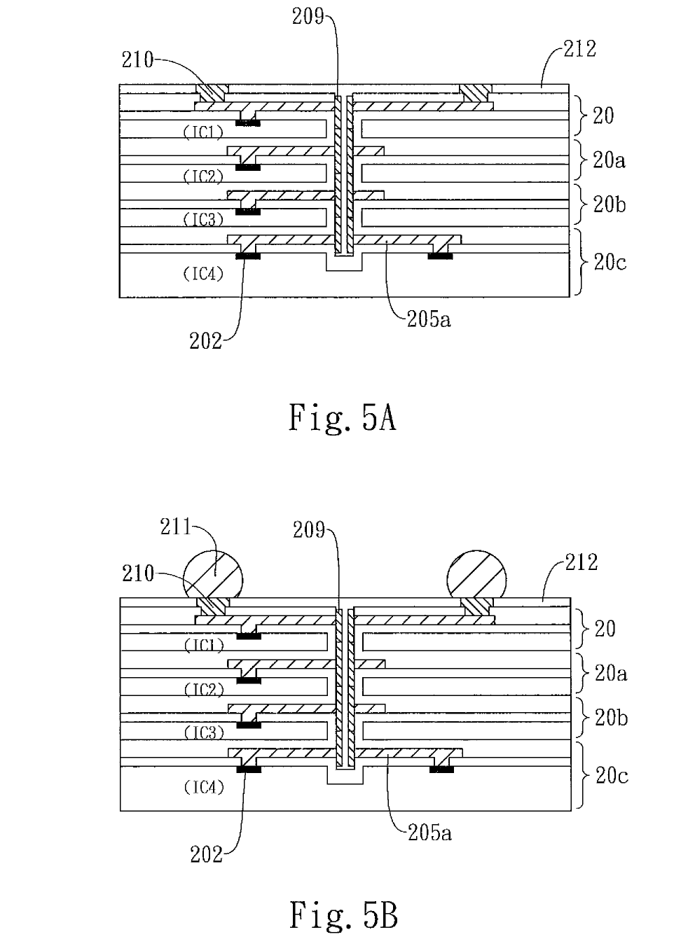

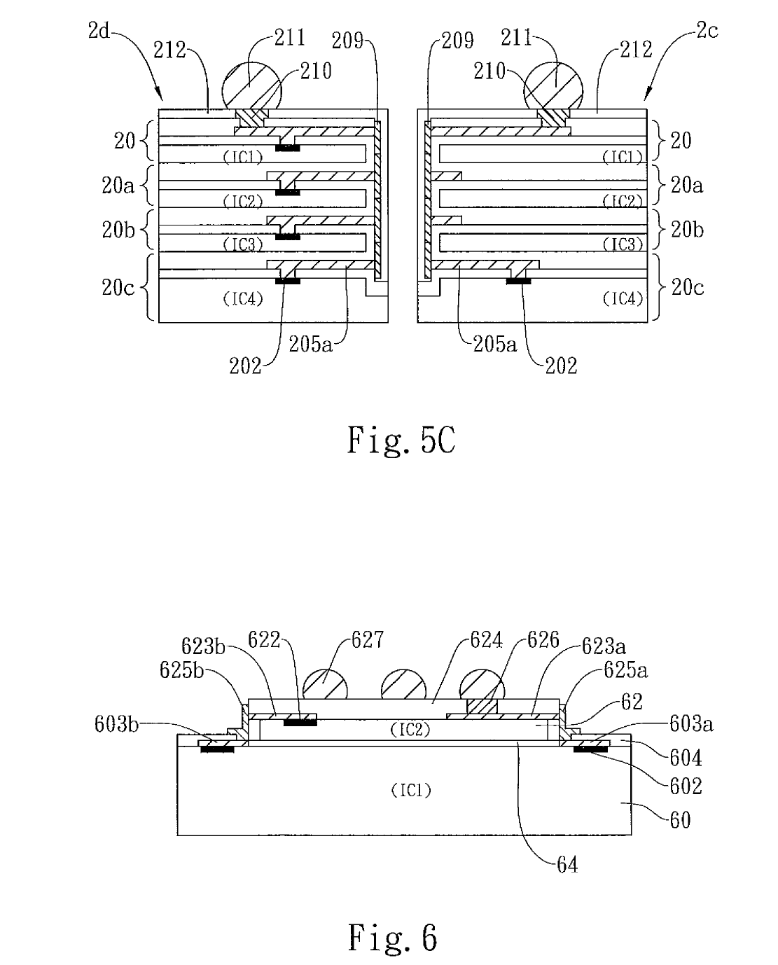

Furthermore, according to the present invention, a protective layer can be formed on the sidewalls of the dice of the structure of three-dimensional stacked dice 2a or 2b, as shown in FIGS. 5A to 5C. FIG. 5A shows that an insulating protective layer 212 is formed above the metal contacts 210 of the top wafer 20 after the step corresponding to FIG. 2H is finished. In this stage, the vertical electrical conductive wires 209 are also covered with the insulating protective layer 212 while the metal contacts 210 are exposed. With reference to FIG. 5B, the conductive bump 211 is formed on one of the metal contacts 210 of the top wafer 20, by which the electrical connection to the external is established. Then the wafer is sawed so as to form the structures of three-dimensional stacked dice 2c and 2d, as shown in FIG. 5C.

With reference to FIG. 6, the structure of three-dimensional stacked dice according to another embodiment of the present invention is shown. In this embodiment, the structure of three-dimensional stacked dice includes two dice of different sizes 60 and 62, which are bonded and stacked with each other with an adhesive layer 64. The die 60 is provided with a plurality of metal pads 602, such as aluminum pads, and on the upper surface of the die 60 a first electrical conductive layer including plural first electrical conductive wires 603a and 603b is formed, for electrically connecting the metal pads 602 to one of the first electrical conductive wires 603a and 603b corresponding thereto. A first insulating layer 604 is formed on the first electrical conductive layer in such a way that a portion of the surface of the respective first electrical conductive wires 603a and 603b is exposed. The die 62 also has a plurality of metal pads 622, such as aluminum pads, and thereon a second electrical conductive layer having a plurality of second electrical conductive wires 623a and 623b is formed. The second electrical conductive wires 623a and 623b are respectively extended to the opposite sidewalls of die, and are laterally exposed there. One of the metal pads 622 of the die 62 is electrically connected to the electrical conductive wire 623b corresponding thereto. The second insulating layer 624 is provided on the second electrical conductive layer so that a portion of the surface of electrical conductive wire 623a is exposed. In this embodiment, the electroless plating process is performed to deposit a metal layer onto the exposed surface of the first electrical conductive wires 603a and 603b as well as the laterally exposed portion of second electrical conductive wires 623a and 623b. The deposited metal layers isotropically grow to contact with each other, and thus a vertical electrical conductive wire 625a located between the first electrical conductive wire 603a and the second electrical conductive wire 623a corresponding thereto is formed as well as a vertical electrical conductive wire 625b located between the first electrical conductive wire 623b and the second electrical conductive wire 623b corresponding thereto is formed. In this stage, a metal contact 626 is deposited and formed in the second insulating layer 624, which electrically contact the second electrical conductive wire 623a corresponding thereto. Next, a plurality of conductive bumps 627, such as solder bumps, are provided on the second insulating layer 624 so as to establish the electrical connection of the second electrical conductive wire 623a to the external. In this embodiment, the first electrical conductive wires 603a and 603b as well as the second electrical conductive wires 623a and 623b are made of the same material as the electrical conductive wires 205a as shown in FIG. 2, while the vertical electrical conductive wires 625a and 625b are made of the same material as the vertical electrical conductive wires 209. Preferably, the thickness of the stacked die 62 is less than 20 μm.

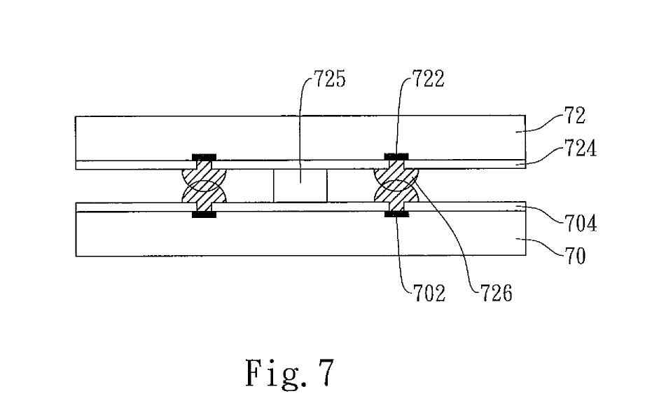

The present invention adopts the electroless plating process to form the electrical conductive wires, and such concept is applicable for establishing the electrical self-interconnections between the opposite metal pads of the respective two dice. With reference to FIG. 7, the structure of three-dimensional stacked dice according to still another embodiment of the present invention is shown. In this embodiment, the stacking structure includes two dice 70 and 72 that are bonded and stacked with each other in a front face-to-front face manner. The die 70 has a plurality of metal pads 702, such as aluminum pads. On the die 70 an insulating layer 704 is formed in such a way that a portion of surface of the metal pads 702 can be exposed. The die 72 also has a plurality of metal pads 722, such as aluminum pads, and on the die 72 a further insulating layer 724 is formed to expose a portion of surface of the metal pads 722. In this embodiment, the dice 70 and 72 are bonded and stacked with each other in a front face-to-front face manner, while the respective metal pads 702 and 722 thereof are aligned with each other. The spacer layer 725 is formed between the dice 70 and 72, so as to provide a space therebetween. In this embodiment, the metal contact 726 is formed between each pair of metal pads 702 and 722 corresponding thereto by means of electroless plating process.

The method of the present invention is applicable in not only the die-to-die stacking, but also in the wafer-level stacking such as the die-to-wafer or wafer-to-wafer stacking.

While the invention has been described by way of examples and in terms of preferred embodiments, it is to be understood that various changes, substitutions, and alterations can be made herein without departing from the spirit and scope of the invention as defined by the appended claims.

What is claimed is:

1. A structure of three-dimensional stacked dice with vertical electrical self-interconnections, comprising:
a plurality of dice three-dimensionally stacked from bottom to top, at least two of which having a plurality of metal pads corresponding to at least a sidewall of die;
a first insulating layer formed on a first surface of each of said dice in such a way that said metal pads are exposed, and on each of said metal pads an electrical contact passing through said first insulating layer is formed;
an electrical conductive wire layer formed on said first insulating layer of each of said dice and comprising a plurality of electrical conductive wires extending to said sidewall of die corresponding to said metal pads, wherein each of said metal pads is electrically connected to a corresponding one of said electrical conductive wires via said electrical contact;
a second insulating layer formed on said first insulating layer of each of said dice in such a way that each die is covered therewith and said electrical conductive wires corresponding to said sidewall of die are exposed; and
a plurality of vertical electrical conductive wires formed on said sidewalls of said dice and electrically connected to said electrical conductive wires exposed to said sidewalls of said dice.

2. The structure of three-dimensional stacked dice with vertical electrical self-interconnections of claim 1, further comprising a plurality of electrical conductive bumps on a first surface of a top one of said dice, which are electrically coupled to said electrical conductive wires corresponding thereto.

3. The structure of three-dimensional stacked dice with vertical electrical self-interconnections of claim 1, wherein said second insulating layer has a function of die-adhering.

4. The structure of three-dimensional stacked dice with vertical electrical self-interconnections of claim 1, further comprising an adhesive layer sandwiched between neighboring two of said dice.

5. The structure of three-dimensional stacked dice with vertical electrical self-interconnections of claim 1, wherein said electrical conductive wires of said electrical conductive layer comprise aluminum or copper.

6. The structure of three-dimensional stacked dice with vertical electrical self-interconnections of claim 1, wherein said electrical conductive wire layer comprises a metal attachment layers made of titanium, titanium tungsten or chrominum.

7. The structure of three-dimensional stacked dice with vertical electrical self-interconnections of claim 1, wherein said vertical electrical conductive wires are formed by means of electroless plating.

8. The structure of three-dimensional stacked dice with vertical electrical self-interconnections of claim 7, wherein said vertical electrical conductive wires comprise copper, nickel, tin, gold or a combination thereof.

9. The structure of three-dimensional stacked dice with vertical electrical self-interconnections of claim 1, wherein each of said dice has a thickness less than 20 μm.

10. The structure of three-dimensional stacked dice with vertical electrical self-interconnections of claim 1, further comprising a protective layer covering said vertical electrical conductive wires.

11. A structure of three-dimensional stacked dice with vertical electrical self-interconnections, comprising:
at least two dice stacked with each other, each of which comprising a plurality of metal pads corresponding to at least a sidewall of die;
an electrical conductive layer formed on a top surface of each of said dice and comprising a plurality of electrical conductive wires, wherein each of said metal pads is electrically connected to one of said electrical conductive wires corresponding thereto;
a first insulating layer formed on a top surface of a lower die of said at least two dice in such a way that a portion of said electrical conductive wires are exposed;
a second insulating layer formed on a top surface of an upper die of said at least two dice in such a way that said upper die is covered therewith and a portion of each of said electrical conductive wires is laterally exposed; and
a plurality of vertical electrical conductive wires formed on said sidewall of said upper die and respectively connecting a laterally exposed one of said electrical conductive wires with one of said electrical conductive wires corresponding to said lower die.

12. The structure of three-dimensional stacked dice with vertical electrical self-interconnections of claim 11, wherein said dice have the same size or different sizes.

13. The structure of three-dimensional stacked dice with vertical electrical self-interconnections of claim 11, further comprising a plurality of electrical conductive bumps on said second insulating layer, wherein at lease one of said electrical conductive wires of said upper die is electrically coupled to one of said electrical conductive bumps.

14. The structure of three-dimensional stacked dice with vertical electrical self-interconnections of claim 11, wherein said vertical electrical conductive wires are formed by means of electroless plating.

15. The structure of three-dimensional stacked dice with vertical electrical self-interconnections of claim 14, wherein said vertical electrical conductive wires comprises copper, nickel, tin, gold or a combination thereof.

16. The structure of three-dimensional stacked dice with vertical electrical self-interconnections of claim 11, wherein said electrical conductive wires of said upper and lower dice comprises aluminum or copper.

17. The structure of three-dimensional stacked dice with vertical electrical self-interconnections of claim 11, wherein said electrical conductive wire layer comprises a metal attachment layers made of titanium, titanium tungsten or chrominum.

18. The structure of three-dimensional stacked dice with vertical electrical self-interconnections of claim 11, further comprising an insulating adhesive layer sandwiched between said upper die and said lower die.

19. The structure of three-dimensional stacked dice with vertical electrical self-interconnections of claim 11, wherein each of said dice has a thickness less than 20 μm.

20. A method for manufacturing a structure of three-dimensional stacked dice with vertical electrical self-interconnections, comprising steps of:
providing a wafer having a plurality of dice formed thereon, between adjacent two of said dice a scribe line being formed and each of said dice having a plurality of metal pads;
forming a recess on each of said scribe lines on said wafer;
forming a first insulating layer on said wafer and forming a plurality of openings therein so as to expose said metal pads;
forming an electrical conductive layer on said first insulating layer, said electrical conductive layer comprising a plurality of electrical conductive wires extending across said recesses, resulting in said metal pads respectively electrically connected to one of said electrical conductive wires corresponding thereto;
forming a second insulating layer on said electrical conductive layer;
attaching a handling substrate to said second insulating layer;
thinning said wafer at a bottom side thereof to a level corresponding to a position of said recess;
removing said handling substrate whereby a wafer comprising said electrical conductive layer is obtained;
stacking and aligned-bonding a plurality of wafers comprising said electrical conductive layer with each other;
forming a groove in each of said scribe lines of said wafers that are aligned and bonded to each other, so as to laterally expose a portion of each of said electrical conductive wires;
performing an electroless plating process so as to form a plurality of vertical electrical conductive wires at a sidewall of each of said grooves to electrically connect said electrical conductive wires that are laterally exposed; and
sawing said wafers to form a plurality of three-dimensional stacked dice.

21. The method for manufacturing a structure of three-dimensional stacked dice with vertical electrical self-interconnections of claim 20, further comprising a step of bonding said wafers to a further wafer that is un-thinned and includes an electrical conductive layer before said groove is formed in each of said scribe lines of said wafers.

22. The method for manufacturing a structure of three-dimensional stacked dice with vertical electrical self-interconnections of claim 20, further comprising a step of forming a plurality of electrical conductive bumps on said second insulating layer of a top wafer of said wafers before said wafers are sawed, so that an electrical connection of each of said three-dimensional stacked dice to the external is established.

23. The method for manufacturing a structure of three-dimensional stacked dice with vertical electrical self-interconnections of claim 20, wherein said second insulating layer has a function of die-adhering.

24. The method for manufacturing a structure of three-dimensional stacked dice with vertical electrical self-interconnections of claim 20, wherein said vertical electrical conductive wires comprise copper, nickel, tin, gold or a combination thereof.

25. A method for manufacturing a die with vertical electrical self-interconnections, comprising steps of:
providing a die having a plurality of metal pads formed on a surface thereof; and
performing an electroless plating process to form a metal layer on an outer surface of each of said metal pads, wherein said metal layers of adjacent two of said metal pads are electrically contact with each other.

26. A method for manufacturing a structure of three-dimensional stacked dice with vertical electrical self-interconnections, comprising the steps of:
providing a first die having a plurality of metal pads below a surface thereof;
forming a first insulating layer on said surface of said first die to expose said metal pads thereof;
providing a second die having a plurality of metal pads below a surface thereof;
forming a second insulating layer on said surface of said second die to expose said metal pads thereof;
forming a spacer layer on said first insulating layer of said first die;
stacking said second die on said first die in a metal pad-to-metal pad manner; and
performing an electroless plating process to form a metal contact between each pair of said metal pads corresponding thereto.
